(19) United States
(12) Patent Application Publication
(10) Pub. No.: US 2026/0173526 A1
(43) Pub. Date: Jun. 18, 2026

(54) TRANSISTOR STACK WITH TRANSISTORS HAVING DIFFERENT ON-RESISTANCE AND OFF-CAPACITANCE VALUES

(71) Applicant: Skyworks Solutions, Inc., Irvine, CA (US)

(72) Inventors: Aniruddha B. Joshi, Irvine, CA (US); John Tzung-Yin Lee, Costa Mesa, CA (US)

(21) Appl. No.: 19/422,241

(22) Filed: Dec. 16, 2025

Related U.S. Application Data
(60) Provisional application No. 63/734,976, filed on Dec. 17, 2024.
(60) Provisional application No. 63/734,948, filed on Dec. 17, 2024.
(60) Provisional application No. 63/734,958, filed on Dec. 17, 2024.

(51) Int. Cl. H10D 86/40; H10D 86/00; H10W 44/20

(52) U.S. Cl. CPC H10D 86/421; H10W 44/248; H10D 86/201

(57) ABSTRACT

A transistor stack comprises a first transistor having a first off-capacitance and a second transistor having a second off-capacitance. The first off-capacitance is greater than the second off-capacitance. The transistor stack further comprises a third transistor having a third off-capacitance, where the second transistor is electrically connected between the first transistor and the third transistor.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

The disclosed technology relates to transistors. Embodiments of this disclosure relate to field effect transistors (FETs) and radio-frequency (RF) devices having a FET stack.

### Description of Related Technology

A field-effect transistor (FET) can be utilized as a switch for radio-frequency (RF) applications. FET-based switches, such as silicon-on-insulator (SOI) switches are used in, for example, antenna switch modules and front-end modules. High performance antenna switches can have a stringent requirement of low insertion loss and isolation. At a transistor level, these translate into low on-resistance (Ron) and off-capacitance (Coff). Traditional technology solutions that lead to lower Coff tend to increase Ron. It can be challenging to reduce the Coff while maintaining a relatively low Ron at the same time.

### SUMMARY

In some aspects, the techniques described herein relate to a transistor stack including: a first transistor having a first off-capacitance; a second transistor having a second off-capacitance, the first off-capacitance being greater than the second off-capacitance; and a third transistor having a third off-capacitance, the second transistor electrically connected between the first transistor and the third transistor.

In some aspects, the techniques described herein relate to a transistor stack wherein the third off-capacitance is greater than the second off-capacitance.

In some aspects, the techniques described herein relate to a transistor stack wherein the first transistor is included in a first set of transistors including other transistors.

In some aspects, the techniques described herein relate to a transistor stack wherein the first transistor and the other transistors in the first set of transistors have gradually varying off-capacitances.

In some aspects, the techniques described herein relate to a transistor stack wherein the second transistor is included in a second set of transistors including other transistors.

In some aspects, the techniques described herein relate to a transistor stack wherein the third transistor is included in a third set of transistors including other transistors.

In some aspects, the techniques described herein relate to a transistor stack wherein the first transistor has a first on-resistance, and the second transistor has a second on-resistance greater than the first on-resistance.

In some aspects, the techniques described herein relate to a transistor stack wherein the third transistor has a third on-resistance, and the second on-resistance is greater than the third on-resistance.

In some aspects, the techniques described herein relate to a transistor stack wherein the first transistor is positioned between a first node and the second transistor.

In some aspects, the techniques described herein relate to a transistor stack wherein the second transistor is positioned between a second node and the second transistor.

In some aspects, the techniques described herein relate to a radio frequency module including an antenna switch having the transistor stack and an acoustic wave filter.

In some aspects, the techniques described herein relate to a transistor stack including: a first transistor having a first on-resistance; a second transistor having a second on-resistance, the second on-resistance being greater than the first on-resistance; and a third transistor having a third off-capacitance, the second transistor electrically connected between the first transistor and the third transistor.

In some aspects, the techniques described herein relate to a transistor stack wherein the second on-resistance is greater than the third on-resistance.

In some aspects, the techniques described herein relate to a transistor stack wherein the first transistor is included in a first set of transistors including other transistors, the second transistor is included in a second set of transistors including other transistors, and the third transistor is included in a third set of transistors including other transistors.

In some aspects, the techniques described herein relate to a transistor stack wherein the first transistor and the other transistors in the first set of transistors have gradually varying off-capacitances.

In some aspects, the techniques described herein relate to a transistor stack wherein the first transistor is positioned between a first node and the second transistor, and the second transistor is positioned between a second node and the second transistor.

In some aspects, the techniques described herein relate to a radio frequency module including an antenna switch having the transistor stack and an acoustic wave filter.

In some aspects, the techniques described herein relate to a method of forming a transistor stack, the method including: providing a first transistor having a first off-capacitance; electrically coupling a second transistor having a second off-capacitance with the first transistor, the first off-capacitance being greater than the second off-capacitance; and electrically coupling a third transistor having a third off-capacitance with the second transistor such that the second transistor is electrically connected between the first transistor and the third transistor.

In some aspects, the techniques described herein relate to a transistor stack wherein the third off-capacitance is greater than the second off-capacitance.

In some aspects, the techniques described herein relate to a transistor stack wherein the first transistor has a first on-resistance, the second transistor has a second on-resistance greater than the first on-resistance, and the third transistor has a third on-resistance less than the second on-resistance.

In some aspects, the techniques described herein relate to a transistor stack including: a first transistor having a first width; a second transistor having a second width, the first width being greater than the second width; and a third transistor having a third width, the second transistor electrically connected between the first transistor and the third transistor.

In some aspects, the techniques described herein relate to a transistor stack wherein the third width is greater than the second width.

In some aspects, the techniques described herein relate to a transistor stack wherein the first transistor has a greater number of fingers than the second transistor.

In some aspects, the techniques described herein relate to a transistor stack wherein the first transistor has a greater width per finger than the second transistor.

In some aspects, the techniques described herein relate to a transistor stack wherein the second transistor has a greater gate-to-gate pitch than the first transistor.

In some aspects, the techniques described herein relate to a transistor stack wherein the first transistor has a greater gate length than the second transistor.

In some aspects, the techniques described herein relate to a transistor stack wherein the first width is in a range between 1.05 and 2 times greater than the second width.

In some aspects, the techniques described herein relate to a transistor stack wherein the first transistor is positioned between a first node and the second transistor.

In some aspects, the techniques described herein relate to a transistor stack wherein the second transistor is positioned between a second node and the second transistor.

In some aspects, the techniques described herein relate to a radio frequency module including an antenna switch having the transistor stack and an acoustic wave filter.

In some aspects, the techniques described herein relate to a transistor stack including: a first transistor having a first length; a second transistor having a second length greater than the first length; and a third transistor having a third length, the second transistor electrically connected between the first transistor and the third transistor.

In some aspects, the techniques described herein relate to a transistor stack wherein the second length is greater than the third length is greater than the second length.

In some aspects, the techniques described herein relate to a transistor stack wherein the first transistor has a first width, the second transistor has a second width, and the first width being greater than the second width.

In some aspects, the techniques described herein relate to a transistor stack the third transistor has a third width, the third width is greater than the second width.

In some aspects, the techniques described herein relate to a transistor stack wherein the first transistor has a greater number of fingers than the second transistor.

In some aspects, the techniques described herein relate to a transistor stack wherein the first transistor has a greater width per finger than the second transistor.

In some aspects, the techniques described herein relate to a transistor stack wherein the second transistor has a greater gate-to-gate pitch than the first transistor.

In some aspects, the techniques described herein relate to a transistor stack wherein the first transistor is positioned between a first node and the second transistor, and the second transistor is positioned between a second node and the second transistor.

In some aspects, the techniques described herein relate to a method of forming a transistor stack, the method including: providing a first transistor having a first width; electrically coupling a second transistor having a second width with the first transistor, the first width being greater than the second width; and electrically coupling a third transistor having a third width with the second transistor such that the second transistor is electrically connected between the first transistor and the third transistor.

In some aspects, the techniques described herein relate to a transistor stack wherein the third width is greater than the second width.

In some aspects, the techniques described herein relate to a transistor stack including: a first transistor including a first semiconductor substrate having a first thickness; a second transistor including a second semiconductor substrate having a second thickness, the first thickness being greater than the second thickness; and a third transistor including a third semiconductor substrate having a third thickness, the second transistor electrically connected between the first transistor and the third transistor.

In some aspects, the techniques described herein relate to a transistor stack wherein the first thickness is at least 100 Å greater than the second thickness.

In some aspects, the techniques described herein relate to a transistor stack wherein the third thickness is greater than the second thickness.

In some aspects, the techniques described herein relate to a transistor stack wherein the first transistor has a greater number of fingers than the second transistor.

In some aspects, the techniques described herein relate to a transistor stack wherein the first transistor has a greater width per finger than the second transistor.

In some aspects, the techniques described herein relate to a transistor stack wherein the second transistor has a greater gate-to-gate pitch than the first transistor.

In some aspects, the techniques described herein relate to a transistor stack wherein the first transistor has a greater gate length than the second transistor.

In some aspects, the techniques described herein relate to a transistor stack wherein the first transistor is positioned between a first node and the second transistor.

In some aspects, the techniques described herein relate to a transistor stack wherein the second transistor is positioned between a second node and the second transistor.

In some aspects, the techniques described herein relate to a radio frequency module including an antenna switch having the transistor stack and an acoustic wave filter.

In some aspects, the techniques described herein relate to a transistor stack including: a first transistor including a first silicon layer having a first thickness; a second transistor including a second silicon layer having a second thickness, the first thickness being greater than the second thickness; and a third transistor including a third silicon layer having a third thickness, the second transistor electrically connected between the first transistor and the third transistor.

In some aspects, the techniques described herein relate to a transistor stack wherein the third thickness is greater than the second thickness.

In some aspects, the techniques described herein relate to a transistor stack wherein the first transistor has a greater number of fingers than the second transistor.

In some aspects, the techniques described herein relate to a transistor stack wherein the first transistor has a greater width per finger than the second transistor.

In some aspects, the techniques described herein relate to a transistor stack wherein the second transistor has a greater gate-to-gate pitch than the first transistor.

In some aspects, the techniques described herein relate to a transistor stack wherein the first transistor has a greater gate length than the second transistor.

In some aspects, the techniques described herein relate to a transistor stack wherein the first transistor is positioned between a first node and the second transistor.

In some aspects, the techniques described herein relate to a transistor stack wherein the second transistor is positioned between a second node and the second transistor.

In some aspects, the techniques described herein relate to a method of forming a transistor stack, the method including: providing a first transistor including a first semiconductor substrate having a first thickness; electrically coupling a second transistor including a second semiconductor substrate having a second thickness with the first transistor, the first thickness being greater than the second thickness; and electrically coupling a third transistor including a third semiconductor substrate having a third thickness with the second transistor such that the second transistor is electrically connected between the first transistor and the third transistor.

In some aspects, the techniques described herein relate to a transistor stack wherein the third thickness is greater than the second thickness.

In some aspects, the techniques described herein relate to a transistor stack wherein the first transistor is positioned between a first node and the second transistor, and the second transistor is positioned between a second node and the second transistor.

### BRIEF DESCRIPTION OF THE DRAWINGS

Embodiments of this disclosure will now be described, by way of non-limiting example, with reference to the accompanying drawings.

FIG. 1 is a schematic block diagram of a transistor stack according to an embodiment.

FIG. 2 illustrates an example schematic circuit topology of a transistor stack according to an embodiment.

FIG. 3A is a schematic top plan view showing an example layout of a transistor stack according to an embodiment.

FIG. 3B is a schematic top plan view showing an example layout of a transistor stack according to an embodiment.

FIG. 3C is a schematic cross-sectional side view of a transistor stack according to an embodiment.

FIG. 3D is a measured space-charged width breakdown of a ten-transistor stack.

FIG. 3E is a graph showing a breakdown voltage corresponding to the ten-transistor stack of FIG. 3D.

FIG. 4 is a schematic diagram of a radio frequency module that includes one or more transistor stacks according to an embodiment.

FIG. 5 is a schematic block diagram of a module that includes duplexers and an antenna switch.

FIG. 6A is a schematic block diagram of a module that includes a power amplifier, a radio frequency switch, and duplexers in accordance with one or more embodiments.

FIG. 6B is a schematic block diagram of a module that includes filters, a radio frequency switch, and a low noise amplifier according to an embodiment.

FIG. 7A is a schematic diagram of a wireless communication device that includes one or more transistor stacks according to an embodiment.

FIG. 7B is a schematic diagram of a wireless communication device that includes one or more transistor stacks according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

In the realm of high-performance antenna switches, low insertion loss and high isolation may be desired. Providing a transistor that enables low insertion loss and high isolation can be significant for the efficiency and performance of the switch in various applications, including telecommunications and wireless communications. Achieving a relatively low insertion loss and a relatively high isolation can relate to having both low on-resistance (Ron) and low off-capacitance (Coff). The Coff can be reduced by thinning a silicon layer in which a transistor (e.g., a field effect transistor (FET)) is formed. While this approach effectively decreases the Coff, it leads to an increase in the Ron. The increase in the Ron adversely affects the switch's performance by elevating the insertion loss. Due to a trade-off between Ron and Coff, it can be challenging to develop high-performance antenna switches.

A plurality of transistors, such as FETs, can be stacked or connected in series between two nodes to withstand higher voltage levels. In the transistor stack, it is generally desired to have the lowest possible resistance and the lowest possible capacitance. However, due to the trade-off between Ron and Coff, either the resistance or the capacitance becomes higher when reducing the other in the transistor stack.

Various embodiments disclosed herein relate to transistor stacks that achieve both low Ron and low Coff by selectively including transistors with different Ron and Coff. A transistor stack according to an embodiment can include a plurality of transistors coupled to one another. The transistors can be coupled in series between a first node and a second node. For example, the transistors can be field effect transistors (FETs).

In some embodiments, the plurality of transistors can include a first set of transistors, a second set of transistors, and a third set of transistors. The first set of transistors can be coupled between the first node and the second set of transistors. The second set of transistors can be coupled to the first set of transistors and the third set of transistors. The third set of transistors can be coupled between the second set of transistors and the second node. The first set of transistors can have one or more transistors including a first transistor, the second set of transistors can one or more transistors including a second transistor, and the third set of transistors can one or more transistors including a third transistor. The first transistor has a first off-capacitance and a first on-resistance, the second transistor has a second off-capacitance and a second on-resistance, and the third transistor has a third off-capacitance and a third on-resistance. The first off-capacitance can be greater than the second off-capacitance and the first on-resistance can be less than the second on-resistance. The third off-capacitance can be greater than the second off-capacitance and the third on-resistance can be less than the second on-resistance.

Due to the substrate loss across the transistor stack (e.g., the FET stack), the transistors (e.g., the FETs) at the ends of stack have higher current. The current can diminish towards a stack center. The performance of the end transistors (e.g., the first set of transistors and the third set of transistors) may be negatively impacted more by a higher resistance than by a higher capacitance, and the middle transistors (e.g., the second set of transistors) may tolerate a higher resistance. Therefore, arranging a transistor with greater off-capacitance and lower on-resistance closer to the ends as disclosed herein can improve the performance of the transistor stack. Primary parameters that can change the Ron and Coff of a transistor can include a finger width (WF), a finger length (LF), and a number of gate fingers (NF). When the WF are kept consistent, the total width can be the product of the WF and the NF.

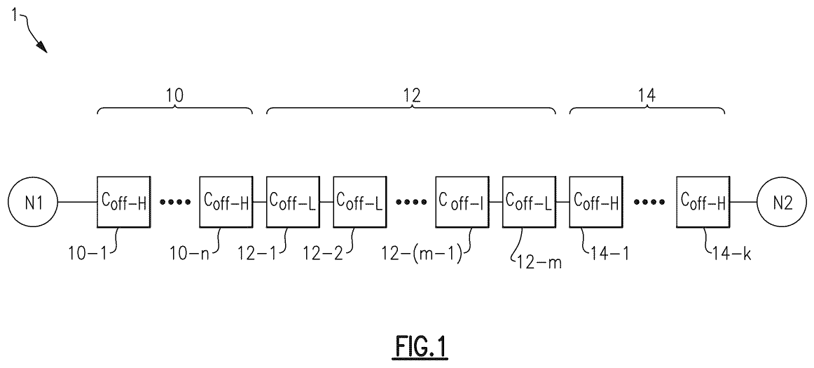

FIG. 1 is a schematic block diagram of a transistor stack 1 according to an embodiment. The transistor stack 1 can be a field effect transistor (FET) stack. The FET stack can include multiple field-effect transistors (FETs) connected in series or parallel to enhance performance in high-power and high-frequency applications, such as RF power amplifiers and low-noise amplifiers. This configuration increases voltage-handling capabilities, improves reliability by reducing stress on individual transistors, and enhances linearity and efficiency, which can be significant for minimizing signal distortion and optimizing power output.

The transistor stack 1 can include a plurality of transistors that include a first set of transistors 10, a second set of transistors 12, and a third set of transistors 14. The first set of transistors 10 can be coupled between a first node N1 and the second set of transistors 12. The second set of transistors 12 can be coupled to the first set of transistors 10 and the third set of transistors 14. The third set of transistors 16 can be coupled between the second set of transistors 14 and the second node N2.

The first set of transistors 10 can have one or more transistors including transistors 10-1 to 10-n, the second set of transistors 12 can one or more transistors including transistors 12-1, 12-2 to 12-(m-1), and 12-m, and the third set of transistors 14 can one or more transistors including transistors 14-1 to 14-k.

The first set of transistors 10 and the third set of transistors 14 can have higher off-capacitance and lower on-resistance than the second set of transistors 12. Therefore, in some embodiments, the first set of transistors 10 and the third set of transistors 14 can be referred to as high off-capacitance resonators and the second set of transistors 12 can be referred to as low off-capacitance resonators. The first set of transistors 10 and the third set of transistors 14 may have the same or different off-capacitance and lower on-resistance.

The transistor 10-1 has a first off-capacitance Coff-1 and a first on-resistance Ron-1, the second transistor 12a has a second off-capacitance Coff-2 and a second on-resistance Ron-2, and the third transistor 14a has a third off-capacitance Coff-3 and a third on-resistance Ron-2. For example, the first off-capacitance Coff-1 can be greater than the second off-capacitance Coff-2. The first on-resistance Ron-1 can be less than the second on-resistance Ron-2. The third off-capacitance Coff-3 can be greater than the second off-capacitance Coff-2 and the third on-resistance Ron-3 can be less than the second on-resistance Ron-2.

The transistors 10-1 to 10-n may have the same or different off-capacitance and lower on-resistance. For example, the transistor 10-1 closer to the first node N1 can have higher off-capacitance and lower on-resistance than the transistor 10-n that is positioned farther away from the first node N1. Similarly, the transistor 12-1 closer to the first node N1 can have higher off-capacitance and lower on-resistance than the transistor 12-2 that is positioned farther away from the first node N1; the transistor 12-m closer to the second node N2 can have higher off-capacitance and lower on-resistance than the transistor 12-(m-1) that is positioned farther away from the second node N2, and the transistor 14-k closer to the second node N2 can have higher off-capacitance and lower on-resistance than the transistor 14-1 that is positioned farther away from the second node N2.

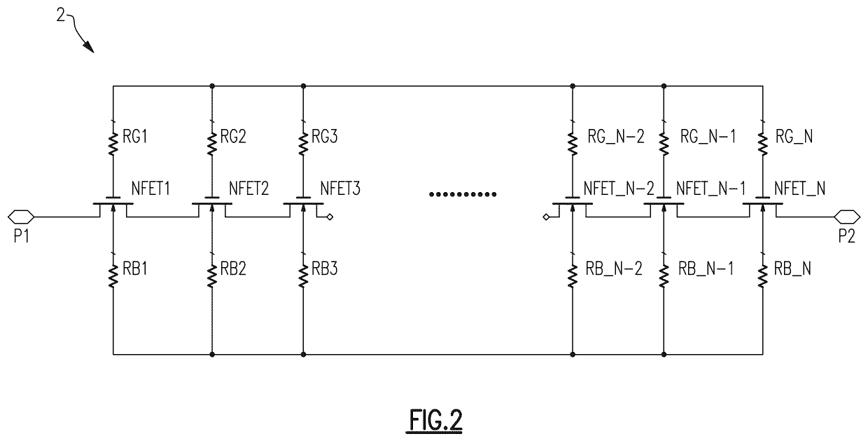

FIG. 2 illustrates an example schematic circuit topology of a transistor stack 2 according to an embodiment. The transistor stack 2 is an example implementation of the transistor stack 1 shown in FIG. 1. The transistor stack 2 can include n-channel field effect transistors (NFETs) electrically coupled in series between a first port P1 and a second port P2. The NFETs can include a first to Nth transistors (e.g., NFET1, NFET2, NFET3, NFET_N-2, NFET_N-1, NFET_N).

The transistor stack 2 can also include passive components, such as resistors. For example, a resistor can be provided in a gate bias line of a transistor of the first to Nth transistors which are illustrated as resistors RG1, RG2, RG3, RG_N-2, RG_N-1, RG_N. Also, a resistor can be provided in a body bias line of a transistor of the first to Nth transistors which are illustrated as resistors RB1, RB2, RB3, RB_N-2, RB_N-1, RB_N.

The NFET1 has an off-capacitance Coff(1) and an on-resistance Ron(1); the NFET2 has an off-capacitance Coff(2) and an on-resistance Ron(2); the NFET3 has an off-capacitance Coff(3) and an on-resistance Ron(3); the NFET_N-2 has an off-capacitance Coff(n-2) and an on-resistance Ron(n-2); the NFET_N-1 has an off-capacitance Coff(n-1) and an on-resistance Ron(n-1); and the NFET_N has an off-capacitance Coff(n) and an on-resistance Ron(n).

In some embodiments, the transistor stack 2 can be configured such that the Coff(1) is greater than the Coff(2), and the Coff(2) is greater than the Coff(3) or the Ron(1) less than Ron(2), and the Ron(2) is less than Ron(3). Also, in some embodiments, the transistor stack 2 can be configured such that the Coff(n) is greater than the Coff(n-1), and the Coff(n-1) is greater than the Coff(n-2) or the Ron(n) less than Ron(n-1), and the Ron(n-1) is less than Ron(n-2). Such relationships between the Coff(1), the Ron(1), the Coff(2), the Ron(2), the Coff(3), the Ron(3), the Coff(n-2), the Ron(n-2), the Coff(n-1), the Ron(n-1), the Coff(n), and the Ron(n) can be achieved by implementing transistors with different designs or non-identical transistors in the transistor stack 2.

In some embodiments, to provide the differences in Coff and Ron in different transistors in the transistor stack 2, widths and/or lengths of the NFET1, the NFET2, and the NFET3 can be different, and widths and/or lengths of the NFET_N-2, the NFET_N-1, and the NFET_N can be different. In a transistor (e.g. a FET), the width can generally refer to the dimension of the transistor's channel that is perpendicular to the current flow between the source and drain terminals, representing the size of the gate that controls the channel conductivity. The Ron can be inversely proportional to the width, and the Coff can be proportional to the width. The length can be the distance between the source and drain terminals along the channel, which determines the path length through which the current must travel and affects the transistor's electrical characteristics such as the on-resistance and speed. The width to length (w/l) ratio can be proportional to the Coff.

For example, the transistor stack 2 can be designed such that a width of the NFET1 is greater than a width of the NFET2, the width of the NFET2 is greater than a width of the NFET3, a width of the NFET_N is greater than a width of the NFET_N-1, and/or the width of the NFET_N-1 is greater than a width of the NFET_N-2.

In some other embodiments, to provide the differences in Coff and Ron in different transistors in the transistor stack 2, different thicknesses of a semiconductor substrate (e.g., a silicon layer) can be used for providing the differences in Coff and Ron. A thicker silicon can provide a higher Coff than a thinner silicon. The thickness difference can be, for example, in a range between 100 Å and 1000 Å. For example, the transistor stack 2 can be designed such that a semiconductor substrate thickness of the NFET1 is greater than a semiconductor substrate thickness of the NFET2, the semiconductor substrate thickness of the NFET2 is greater than a semiconductor substrate thickness of the NFET3, a semiconductor substrate thickness of the NFET_N is greater than a semiconductor substrate thickness of the NFET_N-1, and/or the semiconductor substrate thickness of the NFET_N-1 is greater than the semiconductor substrate thickness of the NFET_N-2.

A skilled artisan will understand that one or more transistors can be added between any two transistors illustrated in the transistor stack 2 of FIG. 2 in accordance with any suitable principles and advantages disclosed herein.

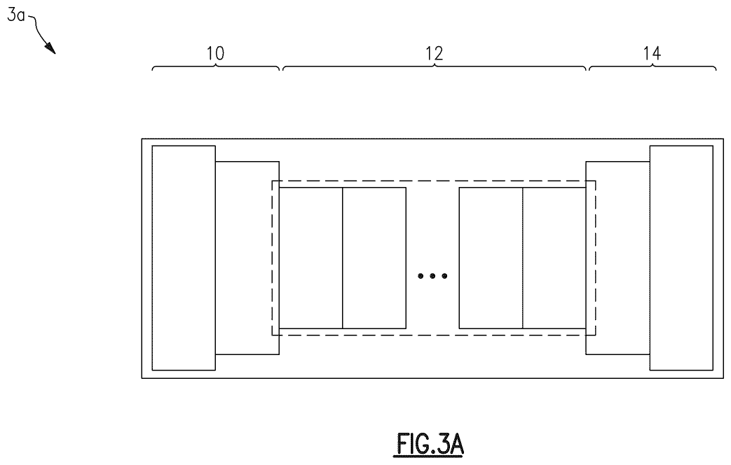

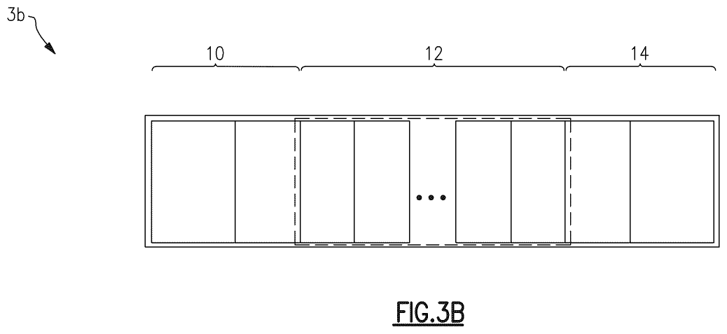

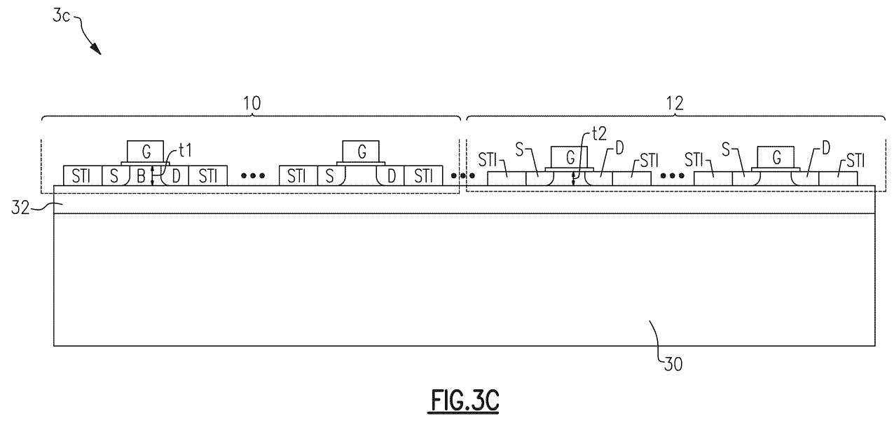

The Coff and the Ron in different transistors in a transistor stack can be provided in any suitable manner. In a transistor (e.g., a FET), a number of fingers refers to the number of gate fingers in a multi-finger layout, and a width per finger can be the width of each individual gate finger. The number of fingers and/or the width per finger can determine the total gate width of the transistor. A gate-to-gate (G2G) pitch can be the center-to-center distance between adjacent gate fingers, including the width of the gate and the spacing between them. A gate length (Lf) can be the effective length of the gate from the source to the drain. These parameters can significantly affect the transistor's Coff and Ron. Increasing the number of fingers and/or the width per finger can increase the overall gate area, which can increase the Coff due to greater parasitic capacitances, while a higher G2G pitch can reduce the Coff by decreasing the capacitive coupling between closely spaced gates. A smaller Lf can reduce the Coff by minimizing overlap capacitances. FIGS. 3A and 3B illustrate different layouts that can provide the differences in Coff and Ron in different transistors in a transistor stack.

FIG. 3A is a schematic top plan view showing an example layout of a transistor stack 3a according to an embodiment. Unless otherwise noted, the components shown in FIG. 3A may be structurally and/or functionally the same as or generally similar to like components disclosed herein. The transistor stack 3a can include a plurality of transistors that include a first set of transistors 10, a second set of transistors 12, and a third set of transistors 14. The second set of transistors 12 can be coupled to the first set of transistors 10 and the third set of transistors 14.

The first set of transistors 10 and the third set of transistors 14 can have lower Ron and higher Coff by having a greater number of fingers than the second set of transistors 12. In the second set of transistors 12, a gate-to-gate (G2G) pitch can be increased as compared to the first set of transistors 10 and/or the third set of transistors 14 to reduce the Coff. Also, a gate length (Lf) of the second set of transistors 12 can be smaller than the first set of transistors 10 and/or the third set of transistors 14 to reduce the Coff.

FIG. 3B is a schematic top plan view showing an example layout of a transistor stack 3b according to an embodiment. Unless otherwise noted, the components shown in FIG. 3B may be structurally and/or functionally the same as or generally similar to like components disclosed herein. The transistor stack 3b can include a plurality of transistors that include a first set of transistors 10, a second set of transistors 12, and a third set of transistors 14. The second set of transistors 12 can be coupled to the first set of transistors 10 and the third set of transistors 14.

The first set of transistors 10 and the third set of transistors 14 can have lower Ron and higher Coff by having a greater width per finger than the second set of transistors 12. In the second set of transistors 12, a gate length (Lf) of the second set of transistors 12 can be smaller than the first set of transistors 10 and/or the third set of transistors 14 to reduce the Coff. As shown in FIGS. 3A and 3B, the lateral size of the transistors of the first set of transistors 10 and the third set of transistors 14 can be greater than the lateral size of the transistors of the second set of transistors 12.

In some embodiments, a width of a transistor in the first set of transistors 10 and/or a width of a transistor in the third set of transistors 14 can be at least 1.05 times, at least 1.1 times, at least 1.2 times, or 1.5 times greater than a width of a transistor of the second set of transistors 12. For example, the width of a transistor in the first set of transistors 10 and/or the width of a transistor in the third set of transistors 14 can be in a range between 1.05 and 2 times or 1.2 and 3 times greater than the width of a transistor of the second set of transistors 12.

In some embodiments, the Coff of a transistor in the first set of transistors 10 and/or the Coff of a transistor in the third set of transistors 14 can have that is at least 1.05 times, at least 1.1 times, at least 1.2 times, or 1.5 times greater than the Coff of a transistor of the second set of transistors 12. For example, the Coff of a transistor in the first set of transistors 10 and/or the Coff of a transistor in the third set of transistors 14 can be in a range between 1.05 and 2 times or 1.2 and 3 times greater than the Coff of a transistor of the second set of transistors 12.

In some embodiments, a difference between a gate length of a transistor in a transistor stack and a gate length of an adjacent transistor can be greater than 0.2 μm. For example, the gate length of a transistor in the first set of transistors 10 and/or the third set of transistors 14 can be greater than the gate length of the second set of transistors 12 in a range between 0.2 μm and 1 μm or 0.5 μm and 2μm. In some embodiments, a product of the number of gate fingers and the width of the gate fingers of a transistor in the first set of transistors 10 and/or the third set of transistors 14 can be at least 1.15 times a product of the number of gate fingers and the width of the gate fingers of a transistor in the second set of transistors 12.

FIG. 3C is a schematic cross-sectional side view of a transistor stack 3c according to an embodiment. Unless otherwise noted, the components shown in FIG. 3C may be structurally and/or functionally the same as or generally similar to like components disclosed herein. The transistor stack 3c includes a substrate 30 (e.g., a silicon substrate), a buried oxide (BOX) layer 32 over the substrate 30, and a plurality of sets of transistors including a first set of transistors 10 and a second set of transistors 12. For example, the substrate can be a high resistive silicon substrate that has resistivity greater than 1 kOhm-cm. Each of the transistors 10, 12 can include a source, a drain, a gate, a base, and a shallow trench isolation. The source, the drain, and the base can be formed in an epitaxial layer. In the transistor stack 3c a thickness of the epitaxial layer (e.g., an Epi thickness t1) of the first set of transistors 10 can be greater than an Epi thickness t2 of the second set of transistors 12. For example, the Epi thickness t1 of the first set of transistors 10 can be at least 100 Å greater than the Epi thickness t2 of the second set of transistors 12. For example, a difference between the Epi thickness t1 and the Epi thickness t2 can be in a range between 100 Å and 1000 Å, 200 Å and 1000 Å, or 200 Å and 500 Å.

FIG. 3D is a measured space-charged width breakdown of a ten-transistor stack. FIG. 3E is a graph showing a breakdown voltage corresponding to the ten-transistor stack of FIG. 3D. The left side of FIGS. 3D and 3E indicates an input side and the right side of FIGS. 3D and 3E indicates an output side. FIGS. 3D and 3E indicate that a more robust transistors are desired at or near the ends of the ten-transistor stack.

When a greater number of gate fingers is implemented, there can be a lower Ron and a higher Coff. Also, when a greater gate finger length is implemented, there can be a higher breakdown voltage (BV) and a higher Ron. Therefore, there is a tradeoff between the Ron, the Coff, and the BV. Epitaxial layer thickness control can be beneficial for controlling the Coff to an optimal level. Thus, the Epi thickness control can enable a transistor stack to include a transistor with a relatively large lateral size, while maintaining the Coff to a desired level.

Any suitable principles and advantages related to transistor stacks disclosed herein can be combined in any suitable manner. In some embodiments, within the first set of transistors 10 there may be gradual change in the Coff and Ron. Similarly, in the second set of transistors 12 and/or in the third set of transistors 14, there may be gradual change in the Coff and Ron.

A method of forming a transistor stack according to an embodiment will be described referring to components shown in FIGS. 1-3B. The method can include providing plurality of transistors and electrically connecting the transistors. The method can include providing a first set of transistors 10, a second set of transistors 12, and a third set of transistors 14. The method can include electrically connecting the first set of transistors 10, the second set of transistors 12, and the third set of transistors 14 in series. The first set of transistors 10 can be coupled between a first node N1 and the second set of transistors 12. The second set of transistors 12 can be coupled to the first set of transistors 10 and the third set of transistors 14. The third set of transistors 16 can be coupled between the second set of transistors 14 and the second node N2.

A transistor stack including any suitable combination of features disclosed herein can be included in a radio frequency (RF) and microwave systems. Transistor stacks (e.g., FET stacks) can be used across various components to enhance performance and reliability. For instance, they are utilized in impedance matching networks to dynamically adjust the impedance between different circuit components, ensuring optimal power transfer and minimal signal reflection. In low-noise amplifiers (LNAs), FET stacks can help amplify weak signals while maintaining low noise levels, which is crucial for preserving signal integrity in sensitive RF front-end circuits. Additionally, FET stacks can be used as active tuning elements to modify the frequency response of filters or circuits, allowing them to adapt to varying operating conditions or frequencies. In switching networks, FET stacks can serve as fast and efficient switches that can route signals or switch between different signal paths with high isolation and low loss. They can also be employed in frequency multipliers and mixers to generate harmonics or mix frequencies, enabling the conversion of signals from one frequency to another, a fundamental function in RF communication. Moreover, in power amplifiers (PAs), FET stacks can handle high power levels and voltages, providing the necessary amplification to drive antennas or subsequent stages while maintaining high efficiency and linearity.

A transistor stack including any suitable combination of features disclosed herein can be included in a system that includes a filter arranged to filter a radio frequency signal in a fifth generation (5G) New Radio (NR) operating band within Frequency Range 1 (FR1). A filter arranged to filter a radio frequency signal in a 5G NR operating band can include one or more resonators. FR1 can be from 410 MHz to 7.125 GHz, for example, as specified in a current 5G NR specification.

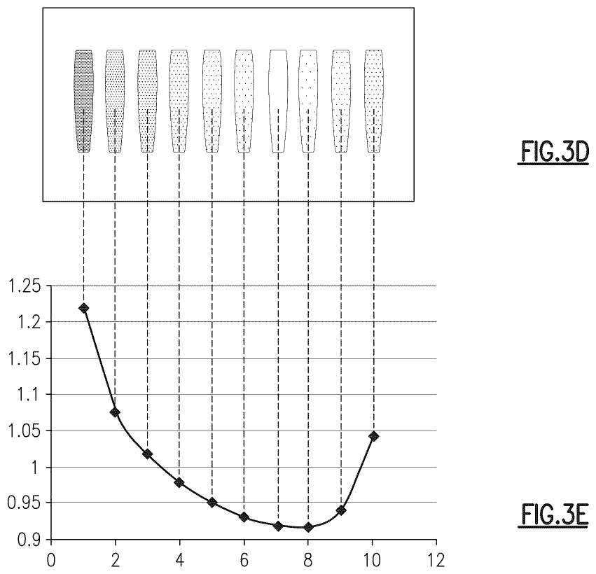

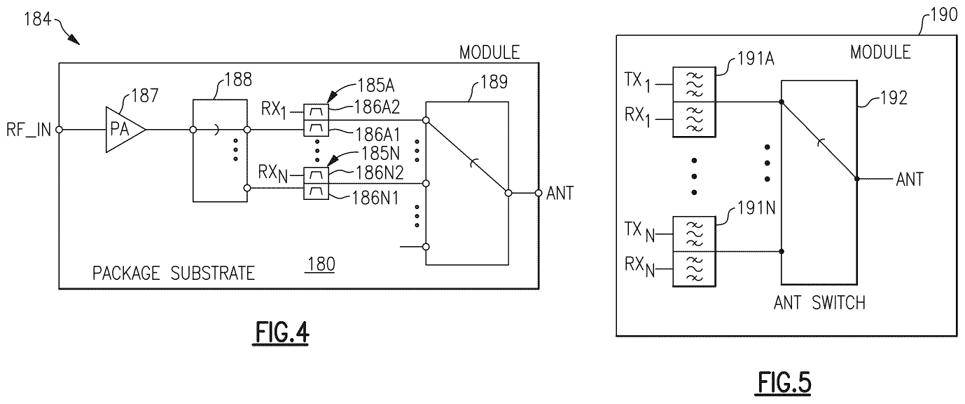

FIG. 4 is a schematic diagram of a radio frequency module 184 that includes one or more transistor stacks according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators. Similarly, one or more of the receive filters 186A2 to 186N2 can include one or more SAW resonators.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 5 is a schematic block diagram of a module 190 that includes duplexers 191A to 191N and an antenna switch 192. The antenna switch 192 can include one or more transistor stacks in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

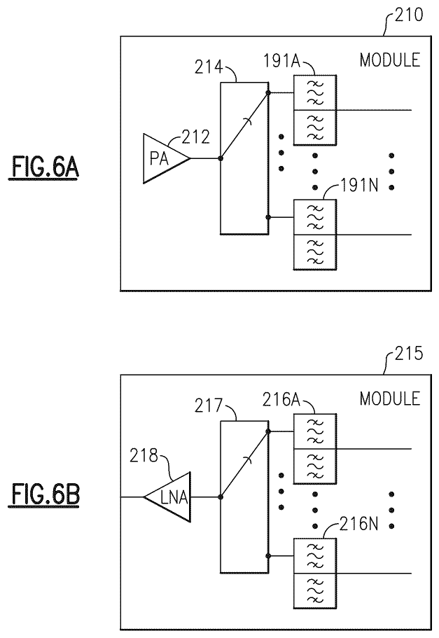

FIG. 6A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators. Any suitable number of duplexers 191A to 191N can be implemented.

FIG. 6B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

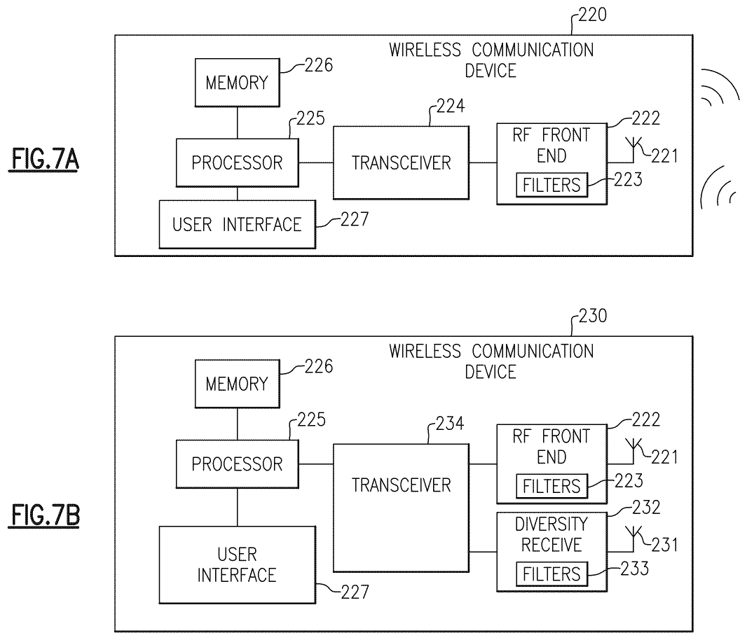

FIG. 7A is a schematic diagram of a wireless communication device 220 that includes one or more transistor stacks according to an embodiment. The wireless communication device 220 can that include filters 223 in a radio frequency front end 222 according to an embodiment. The filters 223 can include one or more SAW resonators. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 7B is a schematic diagram of a wireless communication device 230 that includes one or more transistor stacks according to an embodiment. The wireless communication device 230 can include filters 223 in a radio frequency front end 222 and a second filter 233 in a diversity receive module 232. The wireless communication device 230 is like the wireless communication device 200 of FIG. 7A, except that the wireless communication device 230 also includes diversity receive features. As illustrated in FIG. 7B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A transistor stack, comprising:
a first transistor having a first off-capacitance;
a second transistor having a second off-capacitance, the first off-capacitance being greater than the second off-capacitance; and
a third transistor having a third off-capacitance, the second transistor electrically connected between the first transistor and the third transistor.

2. The transistor stack of claim 1 wherein the third off-capacitance is greater than the second off-capacitance.

3. The transistor stack of claim 1 wherein the first transistor is included in a first set of transistors including other transistors.

4. The transistor stack of claim 3 wherein the first transistor and the other transistors in the first set of transistors have gradually varying off-capacitances.

5. The transistor stack of claim 3 wherein the second transistor is included in a second set of transistors including other transistors.

6. The transistor stack of claim 5 wherein the third transistor is included in a third set of transistors including other transistors.

7. The transistor stack of claim 1 wherein the first transistor has a first on-resistance, and the second transistor has a second on-resistance greater than the first on-resistance.

8. The transistor stack of claim 7 wherein the third transistor has a third on-resistance, and the second on-resistance is greater than the third on-resistance.

9. The transistor stack of claim 1 wherein the first transistor is positioned between a first node and the second transistor.

10. The transistor stack of claim 9 wherein the second transistor is positioned between a second node and the second transistor.

11. A radio frequency module including an antenna switch having the transistor stack of claim 1 and an acoustic wave filter.

12. A transistor stack comprising:
a first transistor having a first on-resistance;
a second transistor having a second on-resistance, the second on-resistance being greater than the first on-resistance; and
a third transistor having a third off-capacitance, the second transistor electrically connected between the first transistor and the third transistor.

13. The transistor stack of claim 12 wherein the second on-resistance is greater than the third on-resistance.

14. The transistor stack of claim 12 wherein the first transistor is included in a first set of transistors including other transistors, the second transistor is included in a second set of transistors including other transistors, and the third transistor is included in a third set of transistors including other transistors.

15. The transistor stack of claim 14 wherein the first transistor and the other transistors in the first set of transistors have gradually varying off-capacitances.

16. The transistor stack of claim 12 wherein the first transistor is positioned between a first node and the second transistor, and the second transistor is positioned between a second node and the second transistor.

17. A radio frequency module including an antenna switch having the transistor stack of claim 12 and an acoustic wave filter.

18. A method of forming a transistor stack, the method comprising:
providing a first transistor having a first off-capacitance;
electrically coupling a second transistor having a second off-capacitance with the first transistor, the first off-capacitance being greater than the second off-capacitance; and
electrically coupling a third transistor having a third off-capacitance with the second transistor such that the second transistor is electrically connected between the first transistor and the third transistor.

19. The method of claim 18 wherein the third off-capacitance is greater than the second off-capacitance.

20. The method of claim 18 wherein the first transistor has a first on-resistance, the second transistor has a second on-resistance greater than the first on-resistance, and the third transistor has a third on-resistance less than the second on-resistance.
